(19) United States
(12) Patent Application Publication
(10) Pub. No.: US 2010/0105207 A1
(43) Pub. Date: Apr. 29, 2010

(54) METHOD FOR FORMING FINE PATTERN OF SEMICONDUCTOR DEVICE

(76) Inventor: Ki-Jun Yun, Suwon-si (KR)

Correspondence Address: SHERR & VAUGHN, PLLC, 620 HERNDON PARKWAY, SUITE 320, HERNDON, VA, 20170, US

(21) Appl. No.: 12/603,630

(22) Filed: Oct. 22, 2009

(30) Foreign Application Priority Data
Oct. 23, 2008 (KR) 10-2008-0104012

(51) Int. Cl. H01L 21/3065

(52) U.S. Cl. 438/694; 257/E21.218

(57) ABSTRACT

A method for forming a fine pattern of a semiconductor device includes forming an insulating layer and an etch layer over a semiconductor substrate, coating a photoresist layer over the etch layer, forming a photoresist pattern by performing a photolithography process for the photoresist layer, forming spacers at sidewalls of the photoresist pattern by performing a primary etching process using the photoresist pattern as a mask, and forming an etch layer pattern and an insulating layer pattern by performing a secondary etching process using the photoresist pattern and the spacers as a mask.

The present application claims priority under 35 U.S.C. 119 to Korean Patent Application No. 10-2008-0104012 (filed on Oct. 23, 2008), which is hereby incorporated by reference in its entirety.

### BACKGROUND

Large scale integration of semiconductor devices is dependent on developing technology to form fine patterns. In forming semiconductor devices with very fine features, a very fine photoresist pattern used as a mask in an etching or ion implantation process during semiconductor device manufacture, is required.

To form such a fine pattern, equipment having a light source with a wavelength enabling superior resolution must be used. Various methods such as the use of a high NA stepper, development of mask technology, and the application of optical proximity correction (OPC), which is a kind of a resolution enhancement technology (RET), have been introduced.

To improve the optical resolution of the stepper, the wavelength of the light source is reduced. For example, when G-line and i-line steppers, with wavelengths of 436 nm and 365 nm, respectively, are used, process resolution of line/space patterns is limited to about 0.7 μm and about 0.5 μm. To form a fine pattern of 0.5 μm or less, a stepper employing a deep ultraviolet ray (DUV) (e.g., a 248 nm-KrF laser or a 193 nm-ArF laser) having a wavelength less than 0.5 μm as a light source must be used.

However, ArF (193 nm) or KrF (248 nm) steppers not only have a price greatly higher than that of the G-line stepper or the i-line stepper, but also carry enormous adjunct equipment costs. In this regard, research has been directed towards improving resolution by advancing the physical properties of photoresist and technologies for the mask.

Particularly, if a KrF fine pattern is formed using an i-line, or an ArF fine pattern is formed using a KrF stepper, investment and product costs can be significantly reduced. In addition, since ArF resist has etch resistance weaker than that of i-line resist, the thin ArF resist makes it difficult to perform an etching process, so that the fine pattern may be deformed.

### SUMMARY

Embodiments relate to a method for forming a fine pattern of a semiconductor device, and more particularly to a method for forming a fine pattern of a semiconductor device, capable of providing a fine pattern through an etching technology while using a typical light source.

Embodiments provide a method for forming a fine pattern through an etching technology while using a light source, which has a limitation when the fine pattern is formed through a photolithography process. In other words, embodiments provide a method for forming an ArF fine pattern using an i-line stepper or a KrF stepper.

According to embodiments, a method for forming a fine pattern may include forming an insulating layer and an etch layer over a semiconductor substrate, coating a photoresist layer over the etch layer, forming a photoresist pattern by performing a photolithography process for the photoresist layer, forming spacers at sidewalls of the photoresist pattern by performing a primary etching process using the photoresist pattern as a mask, and forming an etch layer pattern and an insulating layer pattern by performing a secondary etching process using the photoresist pattern and the spacers as a mask.

According to embodiments, equipment configured to form a fine pattern may include an apparatus configured to form an insulating layer and an etch layer over a semiconductor substrate, coat a photoresist layer over the etch layer, form a photoresist pattern by performing a photolithography process for the photoresist layer, form spacers at sidewalls of the photoresist pattern by performing a primary etching process using the photoresist pattern as a mask, and form an etch layer pattern and an insulating layer pattern by performing a secondary etching process using the photoresist pattern and the spacers as a mask.

### DRAWINGS

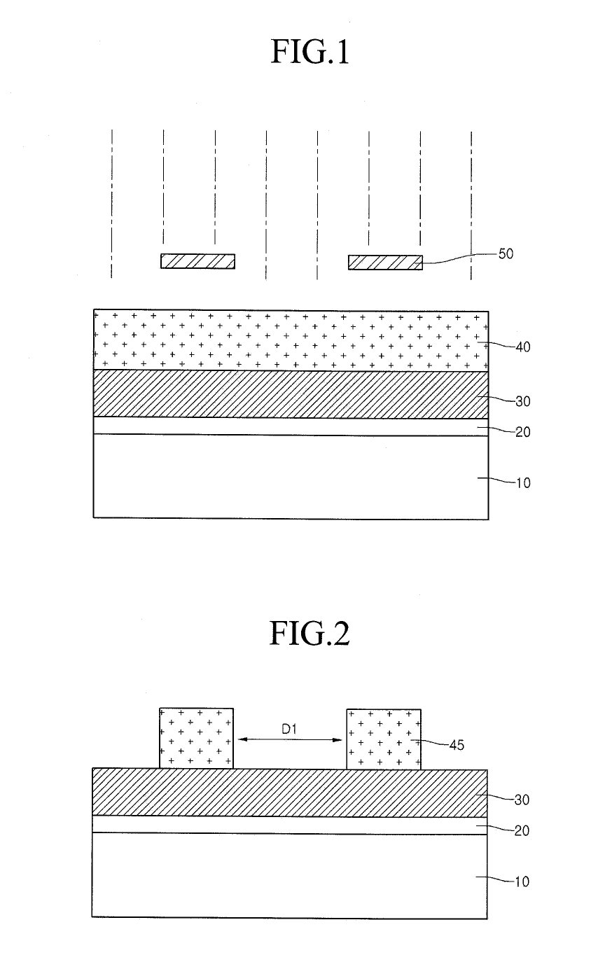

Example FIGS. 1 to 6 are sectional views showing a method for forming a fine pattern of a semiconductor device according to embodiments.

### DESCRIPTION

Hereinafter, a method of forming a fine pattern of a semiconductor device according to embodiments will be described in detail. A method of forming a fine pattern of a semiconductor device according to embodiments will be described with reference to example FIGS. 1 to 6. In the following description, an i-line stepper may be used in a photolithography process.

Referring to example FIG. 1, an insulating layer 20 and a etch layer 30 may be formed over a semiconductor substrate 10. An isolation layer may be formed over a predetermined area of the semiconductor substrate 10 to define an active area and a field area.

The insulating layer 20 formed over the semiconductor substrate 10 may include an oxide layer. The etch layer 30 may be a conductive layer including polysilicon or metal. According to embodiments, the etch layer 30 may be a polysilicon layer.

A photoresist layer 40 may be formed over the etch layer 30. The photoresist layer 40 may be formed over the etch layer 30 through a spin coating scheme. For example, the photoresist layer 40 may be an i-line photoresist layer. An exposure process may be performed with respect to the photoresist layer 40. For example, the exposure process may be selectively performed with respect to the photoresist layer 40 by the i-line stepper, which is an exposure light source, using an exposure mask 50.

Referring to example FIG. 2, a photoresist pattern 45 may be formed over the etch layer 30. The photoresist pattern 45 may be selectively formed over the etch layer 30 through the exposure process using the i-line stepper. Neighboring photoresist patterns 45 may be spaced apart by a first width D1. For example, the space may have a width D1 greater than 0.3 μm (D1>0.3 μm). When photoresist layer 40 is exposed by a KrF stepper, the space may have the first width D1 greater than 0.2 μm (D1>0.2 μm). When the photoresist layer 40 is exposed by an ArF stepper, the space may have the first width D1 greater than 0 μm and smaller than 0.2 μm (0<D1<0.2 μm).

When the i-line stepper is used, since the space of the photoresist pattern 45 has the first width D1 greater than 0.3 μm, the space of the etch layer 30 must be greater than 0.3 μm. Therefore, according to embodiments, when the i-line stepper is used, a KrF fine pattern or an ArF fine pattern can be formed by using a byproduct, which has been generated in an etching process, in order to reduce the space of the photoresist patterns 45.

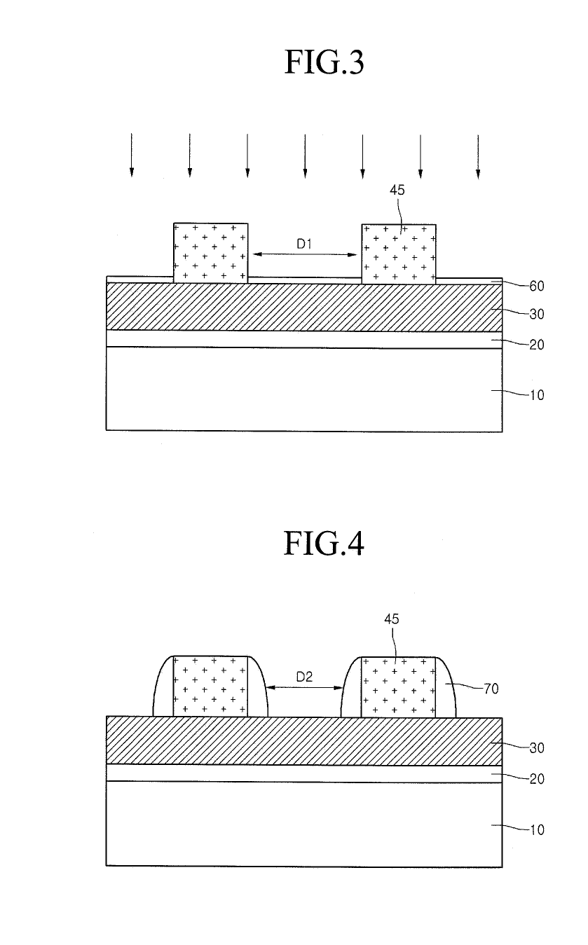

Referring to example FIGS. 3 and 4, spacers 70 may be formed at sidewalls of the photoresist pattern 45. The spacers 70 may be formed by using polymer that is a byproduct generated through a primary etching process. For example, the spacers 70 may include polymer containing SiO or SiC.

As shown in example FIG. 3, the semiconductor substrate 10 may be moved into a poly etcher in order to pattern the etch layer 30, and a native oxide layer 60 similar to a natural oxide layer may be formed over the semiconductor substrate 10. In other words, the spacers 70 may be formed by tuning etching gas and etching time in a breakthrough step to remove the native oxide layer 60.

In particular, the spacers 70 may be formed by depositing a polymer at the sidewalls of the photoresist pattern 45 through a plasma etching process using CₓF_{y} gas by the poly etcher. In the CₓF_{y} gas, x and y may have the ratio of 1:2. For example, the CₓF_{y} gas may be C₄F₆ or C₅F₈.

The primary etching process may be carried out by performing a plasma etching process employing the CₓF_{y} gas while setting high selectivity between the photoresist pattern 45 and a polysilicon layer serving as the etch layer 30. For example, the photoresist pattern 45 and the etch layer 30 may have selectivity of 1:10.

As shown in example FIG. 4, the spacers 70 may be formed at the sidewalls of the photoresist pattern 45 through the primary etching process to remove the native etching layer 60. Accordingly, the spacers 70 between the photoresist patterns 45 may have a second width D2 narrower than the first width D1. For example, the second width D2 may be greater than 0 μm and less than 0.2 μm (0<D2<0.2 μm). In other words, the spacers 70 may be formed at the sidewalls of the photoresist patterns 45 to reduce the space between the neighboring photoresist patterns 45, so that a fine pattern similar to that of the ArF stepper may be formed by the i-line stepper.

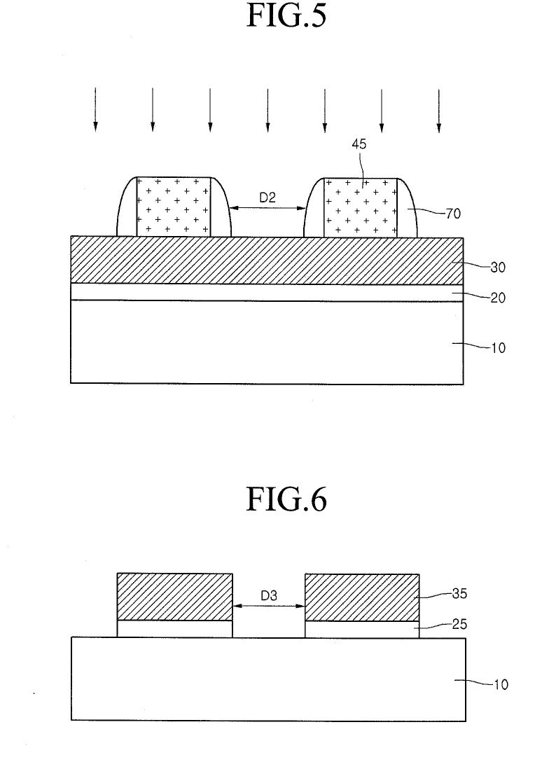

Referring to example FIGS. 5 and 6, a secondary etching process may be performed using the photoresist pattern 45 and the spacers 70 as an etching mask. A etch layer pattern 35 and an insulating layer pattern 24 may be formed over the semiconductor substrate 10. In other words, the secondary etching process is to form a gate or an interconnection by etching the etch layer 30.

The secondary etching process may be performed by using a poly etcher identical to that in the primary etching process. In other words, the primary and secondary etching processes may be performed in an in-situ process. For example, the secondary etching process may be carried out by performing a plasma poly etching process on the etch layer 30 using HBr gas which has high selectivity to the photoresist pattern 45. In addition, when the secondary etching process is performed, the etch layer 30 may be etched by using HBr, Cl₂ and O₂. Thereafter, the photoresist pattern 45 and the spacer 70 may be removed through an ashing process and a cleaning process.

As described above, the insulating layer pattern 25 and the etch layer pattern 35 may be formed over the semiconductor substrate 10 through the secondary etching process using the photoresist pattern 45 and the spacers 70 as a mask. For example, the insulating layer pattern 25 and the etch layer pattern 35 may be used as a gate electrode of the semiconductor device.

The space between neighboring etch layer patterns 35 may have a third width D3. The third width D3 of the space between the etch layer patterns 35 may be identical to the second width D2 of the photoresist patterns 45. In other words, the space between the etch layer patterns 35 may have the width D3 greater than 0 μm and less than 0.2 μm (0<D3<0.2 μm).

As described above, according to embodiments, after forming a photoresist pattern using the i-line stepper, spacers may be formed at the sidewalls of the photoresist pattern. Then, an etching process may be performed by using the photoresist pattern and the spacers as a mask, so that a fine pattern may be formed. Although the fine pattern of the ArF stepper is formed by using the i-line stepper, a fine pattern of the KrF stepper or the ArF stepper may be formed using a G-line stepper or the i-line stepper.

In other words, according to embodiments, a limitation in forming of a fine pattern through an existing photolithography process using an existing light source art can be overcome by forming a fine pattern through the above etching process while using the same light source.

Since polymer is deposited at the sidewalls of the photoresist pattern using a byproduct in a breakthrough step to etch the polysilicon layer, the process steps can be reduced, so that the manufacturing cost can be reduced.

In addition, as the number of process steps have been reduced, defects of the fine pattern are decreased, so that the yield rate can be improved. Also, since a KrF fine pattern or an ArF fine pattern can be formed using the i-line stepper, price competitiveness can be improved by reducing the investment cost for a high-price KrF or ArF stepper to form the fine pattern.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method for forming a fine pattern of semiconductor device comprising:
forming an insulating layer and an etch layer over a semiconductor substrate;
coating a photoresist layer over the etch layer;
forming a photoresist pattern by performing a photolithography process for the photoresist layer;
forming spacers at sidewalls of the photoresist pattern by performing a primary etching process using the photoresist pattern as a mask; and
forming an etch layer pattern and an insulating layer pattern by performing a secondary etching process using the photoresist pattern and the spacers as a mask.

2. The method for forming a fine pattern of semiconductor device of claim 1, wherein the primary and second etching processes are performed in-situ.

3. The method for forming a fine pattern of semiconductor device of claim 1, wherein the forming of the spacers includes:
performing a plasma etching process using CₓF_{y} gas; and
depositing a byproduct, which is generated in the plasma etching process, at the sidewalls of the photoresist pattern.

4. The method for forming a fine pattern of semiconductor device of claim 1, wherein the photoresist pattern and the etch layer have etching selectivity of 1:10 in the primary etching process.

5. The method for forming a fine pattern of semiconductor device of claim 3, wherein the CₓF_{y} gas includes C₄F₆.

6. The method for forming a fine pattern of semiconductor device of claim 3, wherein the CₓF_{y} gas includes C₅F₈.

7. The method for forming a fine pattern of semiconductor device of claim 1, wherein the secondary etching process is a plasma etching process using HBr gas.

8. The method for forming a fine pattern of semiconductor device of claim 1, wherein the secondary etching process is a plasma etching process using HBr, Cl₂ and O₂ gas.

9. The method for forming a fine pattern of semiconductor device of claim 1, wherein the photolithography process is performed by employing G-line equipment.

10. The method for forming a fine pattern of semiconductor device of claim 1, wherein the photolithography process is performed by employing i-line equipment.

11. The method for forming a fine pattern of semiconductor device of claim 1, wherein the photolithography process is performed by employing KrF equipment.

12. The method for forming a fine pattern of semiconductor device of claim 1, wherein the photoresist pattern is spaced from an adjacent photoresist pattern by a first width, and the etch layer pattern is spaced from an adjacent etch layer pattern by a second width which is less than the first width.

13. The method for forming a fine pattern of semiconductor device of claim 1, wherein the primary etching process is a breakthrough step to remove a native oxide layer formed over the etch layer.

14. A fine pattern of semiconductor device configured to:
form an insulating layer and an etch layer over a semiconductor substrate;
coat a photoresist layer over the etch layer;
form a photoresist pattern by performing a photolithography process for the photoresist layer;
form spacers at sidewalls of the photoresist pattern by performing a primary etching process using the photoresist pattern as a mask; and
form an etch layer pattern and an insulating layer pattern by performing a secondary etching process using the photoresist pattern and the spacers as a mask.

15. The fine pattern of semiconductor device of claim 14, wherein the configuration to form the spacers includes apparatus configured to:
perform a plasma etching process using CₓF_{y} gas; and
deposit a byproduct, which is generated in the plasma etching process, at the sidewalls of the photoresist pattern.

16. The fine pattern of semiconductor device of claim 14, wherein the photoresist pattern and the etch layer have etching selectivity of 1:10 in the primary etching process.

17. The fine pattern of semiconductor device of claim 15, wherein the CₓF_{y} gas includes one of C₄F₆ and C₅F₈.

18. The fine pattern of semiconductor device of claim 14, wherein the secondary etching process is a plasma etching process using HBr gas.

19. The fine pattern of semiconductor device of claim 1, wherein the secondary etching process is a plasma etching process using HBr, Cl₂ and O₂ gas.

20. The fine pattern of semiconductor device of claim 1, wherein the photolithography process is performed by employing one of G-line equipment, i-line equipment, and KrF equipment.
